(19) United States
(12) Patent Application Publication
(10) Pub. No.: US 2023/0328877 A1
(43) Pub. Date: Oct. 12, 2023

(54) HIGH FREQUENCY MODULE AND COMMUNICATION APPARATUS

(71) Applicant: Murata Manufacturing Co., Ltd., Kyoto (JP)

(72) Inventors: Yukiya YAMAGUCHI, Kyoto (JP); Takanori UEJIMA, Kyoto (JP); Yuji TAKEMATSU, Kyoto (JP); Dai NAKAGAWA, Kyoto (JP); Kyohei MORITA, Kyoto (JP)

(21) Appl. No.: 18/155,995

(22) Filed: Jan. 18, 2023

Related U.S. Application Data
(63) Continuation of application No. PCT/JP2021/028577, filed on Aug. 2, 2021.

(30) Foreign Application Priority Data
Aug. 12, 2020 (JP) 2020-136489

(51) Int. Cl. H05K 1/18; H05K 3/28; H05K 1/02

(52) U.S. Cl. CPC H05K 1/0271; H05K 1/0225; H05K 1/185; H05K 3/284; H05K 2201/0715; H05K 2201/1003; H05K 2201/1006; H05K 2201/10522; H05K 2201/10545; H05K 2203/025

(57) ABSTRACT

The high frequency module includes a mounting substrate, a circuit component, a resin layer, and a shield layer. The mounting substrate has a first main surface and a second main surface that face each other. The circuit component is mounted on the first main surface of the mounting substrate. The resin layer is disposed on the first main surface of the mounting substrate and covers at least part of an outer peripheral surface of the circuit component. The shield layer covers at least part of the resin layer and a main surface of the circuit component that is far from the mounting substrate. The high frequency module has a gap at at least one of a position between the circuit component and the resin layer, a position between the circuit component and the shield layer, a position inside the resin layer, and a position inside the shield layer.

### CROSS REFERENCE TO RELATED APPLICATION

This is a continuation of International Application No. PCT/JP2021/028577 filed on Aug. 2, 2021 which claims priority from Japanese Patent Application No. 2020-136489 filed on Aug. 12, 2020. The contents of these applications are incorporated herein by reference in their entireties.

### BACKGROUND OF THE DISCLOSURE

### Field of the Disclosure

The present disclosure relates to a high frequency module and a communication apparatus, and more particularly, to a high frequency module and a communication apparatus including a circuit component, a resin, and a shield electrode.

### Description of the Related Art

In Patent Document 1, a high frequency module including a mounting substrate having a first main surface and a second main surface, a transmission power amplifier (circuit component) mounted on the first main surface of the mounting substrate, a resin member (resin layer) covering the transmission power amplifier, and a shield electrode layer (shield layer) is disclosed.

In the high frequency module disclosed in Patent Document 1, the shield electrode layer is formed to cover top and side surfaces of the resin member.

Patent Document 1: International Publication No. 2019/181590

### BRIEF SUMMARY OF THE DISCLOSURE

In a high frequency module, the stress generated by the thermal expansion and contraction or the like inside the high frequency module may be required to be reduced.

A possible benefit of the present disclosure is to provide a high frequency module and a communication apparatus capable of reducing the stress generated by the thermal expansion and contraction or the like inside the high frequency module.

A high frequency module according to an aspect of the present disclosure includes a mounting substrate, a circuit component, a resin layer, and a shield layer. The mounting substrate has a first main surface and a second main surface that face each other. The circuit component is mounted on the first main surface of the mounting substrate. The resin layer is disposed on the first main surface of the mounting substrate and covers at least part of an outer peripheral surface of the circuit component. The shield layer covers at least part of the resin layer and a main surface of the circuit component that is far from the mounting substrate. The high frequency module has a gap at at least one of a position between the circuit component and the resin layer, a position between the circuit component and the shield layer, a position inside the resin layer, and a position inside the shield layer.

A communication apparatus according to an aspect of the present disclosure includes the high frequency module according to the above-mentioned aspect and a signal processing circuit. The signal processing circuit is connected to the high frequency module and performs signal processing on a high frequency signal.

A high frequency module and a communication apparatus according to the present disclosure can reduce the stress generated by the thermal contraction and expansion or the like inside the high frequency module.

### BRIEF DESCRIPTION OF THE SEVERAL VIEWS OF THE DRAWINGS

FIG. 1 is a circuit configuration diagram of a high frequency module and a communication apparatus according to an embodiment.

FIG. 2 is a plan view illustrating a first main surface of a mounting substrate of the high frequency module.

FIG. 3 is a plan view of a second main surface of the mounting substrate of the high frequency module when seen through from the first main surface side of the mounting substrate.

FIG. 4 is a cross-section view taken along A1-A1 in FIG. 2.

FIG. 5 is a cross-section view taken along A2-A2 in FIG. 2.

FIG. 6A is a partial enlarged view of FIG. 2. FIG. 6B is a cross-section view taken along A3-A3 in FIG. 6A.

FIG. 7 is a partial enlarged view of FIG. 6A.

FIG. 8 is an enlarged view of a range W1 in FIG. 7.

FIG. 9 is an enlarged view of a range W2 in FIG. 7.

FIG. 10 is an enlarged view of a range W3 in FIG. 7.

FIG. 11A is a cross-section view taken along A4-A4 in FIG. 7. FIG. 11B is a cross-section view illustrating a modification of the example illustrated in FIG. 11A.

FIG. 12 is a cross-section view illustrating another modification of the example illustrated in FIG. 11A.

FIG. 13 is a cross-section view taken along A5-A5 in FIG. 7.

FIGS. 14A to 14C are explanatory diagrams for explaining an example of a method for manufacturing a high frequency module.

FIG. 15 is a partial cross-section view of a high frequency module according to a first modification.

FIG. 16 is a cross-section view of a high frequency module according to a second modification.

### DETAILED DESCRIPTION OF THE DISCLOSURE

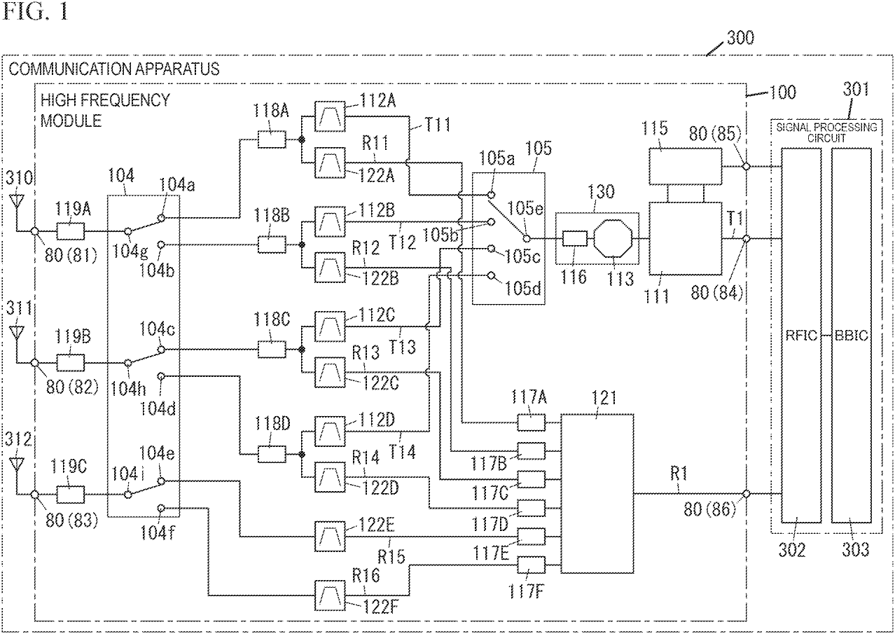

FIGS. 1 to 16, which will be referred to in embodiments and the like described below, are schematic diagrams, and ratios of sizes and thicknesses of component elements in the drawings do not necessarily reflect actual dimensional ratios.

### Embodiments

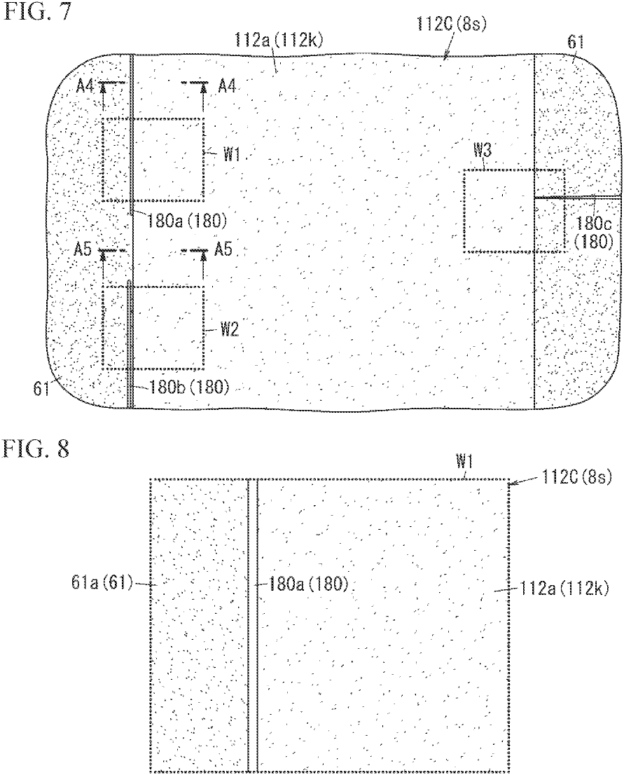

As illustrated in FIG. 4, a high frequency module 100 according to an embodiment includes a mounting substrate 9, a transmission filter 112C, which is an example of a circuit component 8S, a resin layer 61, and a shield layer 5. The mounting substrate 9 has a first main surface 91 and a second main surface 92 that face each other. The transmission filter 112C is mounted on the first main surface 91 of the mounting substrate 9. The resin layer 61 is disposed on the first main surface 91 of the mounting substrate 9 and covers at least part of an outer peripheral surface of the transmission filter 11C. The shield layer 5 covers at least part of the resin layer 61 and a main surface 112a of the transmission filter 112C that is far from the mounting substrate 9. A gap 180 is arranged at least one of a position between the transmission filter 112C and the resin layer 61, a position between the transmission filter 112C and the shield layer 5, a position inside the resin layer 61, and a position inside the shield layer 5 (see FIGS. 7 to 13). With this arrangement, the gap 180 allows the stress generated by the thermal expansion and contraction or the like inside the high frequency module 100 to be reduced.

The high frequency module 100 and a communication apparatus 300 according to the embodiments will be described below with reference to FIGS. 1 to 14.

### High Frequency Module and Communication Apparatus

### (1.1) Circuit Configuration of High Frequency Module and Communication Apparatus

First, a circuit configuration of the high frequency module 100 and the communication apparatus 300 according to an embodiment will be described with reference to FIG. 1.

The high frequency module 100 according to an embodiment is used for, for example, the communication apparatus 300. The communication apparatus 300 is, for example, a mobile phone (for example, a smartphone). However, the communication apparatus 300 is not necessarily a mobile phone and may be, for example, a wearable terminal (for example, a smartwatch). The high frequency module 100 is, for example, a module capable of supporting 4G (fourth generation mobile communication) standards and 5G (fifth generation mobile communication) standards. The 4G standards are, for example, 3GPP LTE standards (LTE: Long Term Evolution). The 5G standards are, for example, 5G NR (New Radio). The high frequency module 100 is a module capable of supporting carrier aggregation and dual connectivity.

For example, the high frequency module 100 is configured to be capable of amplifying a transmission signal (high frequency signal) inputted from a signal processing circuit 301 and outputting the amplified transmission signal to an antenna 310. The high frequency module 100 is also configured to be capable of amplifying a reception signal (high frequency signal) inputted from the antenna 310 and outputting the amplified reception signal to the signal processing circuit 301. The signal processing circuit 301 is not a component element of the high frequency module 100 but is a component element of the communication apparatus 300 that includes the high frequency module 100. For example, the high frequency module 100 is controlled by the signal processing circuit 301 provided in the communication apparatus 300. The communication apparatus 300 includes the high frequency module 100 and the signal processing circuit 301. The communication apparatus 300 further includes antennas 310 to 312.

The signal processing circuit 301 includes, for example, an RF signal processing circuit 302 and a baseband signal processing circuit 303. The signal processing circuit 301 is connected to the high frequency module 100 and performs signal processing on a high frequency signal transferred to and from the high frequency module 100.

For example, the RF signal processing circuit 302 is an RFIC (Radio Frequency Integrated Circuit) and performs signal processing on a high frequency signal. For example, the RF signal processing circuit 302 performs signal processing such as up-conversion on a high frequency signal (transmission signal) outputted from the baseband signal processing circuit 303 and outputs the high frequency signal on which signal processing has been performed. Furthermore, for example, the RF signal processing circuit 302 performs signal processing such as down-conversion on a high frequency signal (reception signal) outputted from the high frequency module 100 and outputs the high frequency signal on which signal processing has been performed to the baseband signal processing circuit 303.

The baseband signal processing circuit 303 is, for example, a BBIC (Baseband Integrated Circuit). The baseband signal processing circuit 303 generates an I-phase signal and a Q-phase signal from a baseband signal. The baseband signal is, for example, an audio signal, an image signal, or the like inputted from the outside. The baseband signal processing circuit 303 combines an I-phase signal with a Q-phase signal to perform IQ modulation processing, and outputs a transmission signal. At this time, a transmission signal is generated as a modulation signal (IQ signal) that is obtained by modulating the amplitude of a carrier signal of a predetermined frequency, the amplitude modulation being performed at a period longer than the period of the carrier signal. For example, a reception signal processed by the baseband signal processing circuit 303 is used as an image signal for image display or an audio signal for conversation.

The high frequency module 100 transfers high frequency signals (reception signals and transmission signals) to and from the antennas 310 to 312 and the signal processing circuit 301. The high frequency module 100 includes a power amplifier 111 and a low noise amplifier 121. The high frequency module 100 also includes a plurality of (in the illustrated example, four) transmission filters 112A to 112D and a plurality of (in the illustrated example, six) reception filters 122A to 122F. The high frequency module 100 also includes a transformer 113, a matching circuit 116, matching circuits 117A to 117F, matching circuits 118A to 118D, and matching circuits 119A to 119C. The high frequency module 100 also includes a first switch 104 and a second switch 105. The high frequency module 100 also includes a controller 115.

The high frequency module 100 includes a plurality of external connection terminals 80. The plurality of external connection terminals 80 include antenna terminals 81 to 83, signal input terminals 84 and 85, a signal output terminal 86, and a plurality of ground terminals 87 (see FIG. 4). The plurality of ground terminals 87 are terminals that are electrically connected to a ground electrode provided in the communication apparatus 300, and a ground potential is provided to the plurality of ground terminals 87.

The power amplifier 111 is provided on a signal path T1 for transmission signals. The power amplifier 111 includes an input terminal and an output terminal.

The input terminal of the power amplifier 111 is connected to the signal processing circuit 301 with the signal input terminal 84 interposed therebetween. The signal input terminal 84 is a terminal through which a high frequency signal (transmission signal) from the signal processing circuit 301 is inputted to the high frequency module 100. The output terminal of the power amplifier 111 is connected to a common terminal 105e of the second switch 105 with the transformer 113 and the matching circuit 116 interposed therebetween. The power amplifier 111 is controlled by the controller 115.

The power amplifier 111 amplifies a transmission signal of a first frequency band inputted to the input terminal and outputs the amplified transmission signal through the output terminal. The first frequency band includes, for example, four communication bands (first to fourth communication bands). The first to fourth communication bands correspond to transmission signals passing through the transmission filters 112A to 112D in a one-to-one relationship. For example, the first to fourth communication bands are different four communication bands among frequency bands defined by the 3GPP LTE standards and the 5G NR standards.

The low noise amplifier 121 is provided on a signal path R1 for reception signals. The low noise amplifier 121 includes six input terminals and one output terminal.

The six input terminals of the low noise amplifier 121 correspond to the six matching circuits 117A to 117F in a one-to-one relationship and correspond to the six reception filters 122A to 122F in a one-to-one relationship. The six input terminals of the low noise amplifier 121 are connected to the corresponding reception filters 122A to 122F with the corresponding matching circuits 118A to 118D interposed therebetween. The output terminal of the low noise amplifier 121 is connected to the signal processing circuit 301 with the signal output terminal 86 interposed therebetween. The signal output terminal 86 is a terminal through which a high frequency signal (reception signal) from the low noise amplifier 121 is outputted to the signal processing circuit 301.

The low noise amplifier 121 amplifies a reception signal of a second frequency band inputted to one of the six input terminals and outputs the amplified reception signal through the output terminal. For example, the second frequency band is wider than the first frequency band and includes first to sixth communication bands.

For example, the transmission filters 112A to 112D are filters that use transmission bands of the first to fourth communication bands as pass bands. For example, the reception filters 122A to 122F are filters that use reception bands of the first to sixth communication bands as pass bands. In this embodiment, the transmission filter 112A and the reception filter 122A, the transmission filter 112B and the reception filter 122B, the transmission filter 112C and the reception filter 122C, and the transmission filter 112D and the reception filter 122D configure separate duplexers (DPXs).

The first switch 104 includes a plurality of (in the illustrated example, three) common terminals 104g to 104i and a plurality of (in the illustrated example, six) selection terminals 104a to 104f.

The three common terminals 104g to 104i correspond to the three matching circuits 119A to 119C in a one-to-one relationship and correspond to the three antenna terminals 81 to 83 in a one-to-one relationship. The three common terminals 104g to 104i are connected to the corresponding antenna terminals 81 to 83 with the corresponding matching circuits 119A to 119C interposed therebetween. The three antenna terminals 81 to 83 correspond to the three antennas 310 to 312 in a one-to-one relationship and are connected to the corresponding antennas 310 to 312.

The four selection terminals 104a to 104d, out of the six selection terminals 104a to 104f, correspond to the four matching circuits 118A to 118D in a one-to-one relationship and correspond to four connection points 123A to 123D in a one-to-one relationship. The selection terminals 104a to 104d are connected to the corresponding connection points 123A to 123D with the corresponding matching circuits 118A to 118D interposed therebetween. The four connection points 123A to 123D correspond to the four transmission filters 112A to 112D in a one-to-one relationship and correspond to the four reception filters 122A to 122D in a one-to-one relationship. The connection points 123A to 123D are points of connection between output terminals of the corresponding transmission filters 112A to 112D and input terminals of the corresponding reception filters 122A to 122D. The remaining two selection terminals 104e and 104f correspond to the two reception filters 122E and 122F in a one-to-one relationship and are connected to input terminals of the corresponding reception filters 122E and 122F.

The first switch 104 switches each of the connection destinations for the three common terminals 104g to 104i to at least one of the six selection terminals 104a to 104f in accordance with a control signal from the signal processing circuit 301. The first switch 104 is, for example, a switch capable of one-to-one and one-to-many connections. The first switch 104 is, for example, a switch IC.

The second switch 105 includes a plurality of (in the illustrated example, four) selection terminals 105a to 105d and the common terminal 105e. The common terminal 105e is connected to the output terminal of the power amplifier 111 with the matching circuit 116 and the transformer 113 interposed therebetween. The four selection terminals 105a to 105d correspond to the four transmission filters 112A to 112D in a one-to-one relationship and are connected to the input terminals of the corresponding transmission filters 112A to 112D.

The second switch 105 switches a connection destination for the common terminal 105e to at least one of the four selection terminals 105a to 105d in accordance with a control signal from the signal processing circuit 301. The second switch 105 is, for example, a switch capable of one-to-one and one-to-many connections. The second switch 105 is, for example, a switch IC. The second switch 105 is a switch having a function for switching between signal paths T11 to T14 for transmission signals of different communication bands.

The transformer 113 and the matching circuit 116 are provided on a signal path between the output terminal of the power amplifier 111 and the common terminal 105e of the second switch 105. More particularly, the transformer 113 is provided between the power amplifier 111 and the matching circuit 116, and the matching circuit 116 is provided between the power amplifier 111 and the common terminal 105e. The transformer 113 and the matching circuit 116 are circuits for achieving the impedance matching between the power amplifier 111 and the transmission filters 112A to 112D. The matching circuit 116 is, for example, an inductor.

The six matching circuits 117A to 117F correspond to the six reception filters 122A to 122F in a one-to-one relationship and correspond to the six input terminals of the low noise amplifier 121 in a one-to-one relationship. The matching circuits 117A to 117F are connected to signal paths between the output terminals of the corresponding reception filters 122A to 122F and the corresponding input terminals of the low noise amplifier 121. The matching circuits 117A to 117F are circuits for achieving the impedance matching between the corresponding reception filters 122A to 122F and the low noise amplifier 121.

The four matching circuits 118A to 118D correspond to the four transmission filters 112A to 112D in a one-to-one relationship and correspond to the four selection terminals 104a to 104d of the first switch 104 in a one-to-one relationship. The four matching circuits 118A to 118D are connected to signal paths between the output terminals of the corresponding transmission filters 112A to 112D and the corresponding selection terminals 104a to 104d of the first switch 104. The four matching circuits 118A to 118D are circuits for achieving the impedance matching between the corresponding transmission filters 112A to 112D and the first switch 104.

The three matching circuits 119A to 119C correspond to the three antennas 310 to 312 in a one-to-one relationship and correspond to the three common terminals 104g to 104i of the first switch 104 in a one-to-one relationship. The three matching circuits 119A to 119C are connected to signal paths between the corresponding antennas 310 to 312 and the corresponding common terminals 104g to 104i of the first switch 104. The three matching circuits 119A to 119C are circuits for achieving the impedance matching between the corresponding antennas 310 to 312 and the first switch 104.

The controller 115 is connected to the power amplifier 111. The controller 115 is also connected to the signal processing circuit 301 with the signal input terminal 85 interposed therebetween. The controller 115 controls the power amplifier 111 in accordance with a control signal from the signal processing circuit 301.

### (1.2) Operations of High Frequency Module And Communication Apparatus

Operations of the high frequency module 100 and the communication apparatus 300 will be described with reference to FIG. 1.

As illustrated in FIG. 1, the high frequency module 100 includes the signal path T1 for transmission signals and the signal path R1 for reception signals.

The signal path T1 includes four signal paths T11 to T14. The signal path T11 is a path passing through the signal input terminal 84, the power amplifier 111, the transformer 113, the matching circuit 116, the second switch 105, the transmission filter 112A, the matching circuit 118A, and the selection terminal 104a in that order. The signal path T12 is a path passing through the signal input terminal 84, the power amplifier 111, the transformer 113, the matching circuit 116, the second switch 105, the transmission filter 112B, the matching circuit 118B, and the selection terminal 104b in that order. The signal path T13 is a path passing through the signal input terminal 84, the power amplifier 111, the transformer 113, the matching circuit 116, the second switch 105, the transmission filter 112C, the matching circuit 118C, and the selection terminal 104c in that order. The signal path T14 is a path passing through the signal input terminal 84, the power amplifier 111, the transformer 113, the matching circuit 116, the second switch 105, the transmission filter 112D, the matching circuit 118D, and the selection terminal 104d in that order.

The signal path R1 includes six signal paths R11 to R16. The signal path R11 is a path passing through the selection terminal 104a, the matching circuit 118A, the reception filter 122A, the matching circuit 117A, the low noise amplifier 121, and the signal output terminal 86 in that order. The signal path R12 is a path passing through the selection terminal 104b, the matching circuit 118B, the reception filter 122B, the matching circuit 117B, the low noise amplifier 121, and the signal output terminal 86 in that order. The signal path R13 is a path passing through the selection terminal 104c, the matching circuit 118C, the reception filter 122C, the matching circuit 117C, the low noise amplifier 121, and the signal output terminal 86 in that order. The signal path R14 is a path passing through the selection terminal 104d, the matching circuit 118D, the reception filter 122D, the matching circuit 117D, the low noise amplifier 121, and the signal output terminal 86 in that order. The signal path R15 is a path passing through the selection terminal 104e, the reception filter 122E, the matching circuit 117E, the low noise amplifier 121, and the signal output terminal 86 in that order. The signal path R16 is a path passing through the selection terminal 104f, the reception filter 122F, the matching circuit 117F, the low noise amplifier 121, and the signal output terminal 86 in that order.

In the second switch 105, at the time of transmission of a transmission signal, the common terminal 105e is connected to at least one of the four selection terminals 105a to 105d (for example, T11 and T12). Thus, at least one signal path (for example, T11 and T12) among the four signal paths T11 to T14 is selected. Furthermore, the first switch 104 connects the at least one selection terminal (for example, 104a and 104b), to which the at least one selected signal path (for example, T11 and T12) is connected, to a corresponding common terminal (for example, 104g and 104h) out of the three common terminals 104g to 104i. Thus, the at least one selected signal path (for example, T11 and T12) is connected to a corresponding antenna out of the three antennas 310 to 312.

In the above-mentioned connection state of the first switch 104 and the second switch 105, a transmission signal is inputted to the signal input terminal 84 from the signal processing circuit 301. The input transmission signal travels through the signal path (for example, T11 and T12) selected by the second switch 105 and is transmitted out of the antenna (for example, 310 and 311) selected by the first switch 104.

As described above, in the second switch 105, when the common terminal 105e is connected to one of the four selection terminals 105a to 105d, a transmission signal can be transmitted using a communication band. Meanwhile, when the common terminal 105e is connected to a plurality of selection terminals among the four selection terminals 105a to 105d, a transmission signal can be transmitted using a plurality of communication bands.

In the first switch 104, at the time of reception of a reception signal, at least one of the three common terminals 104g to 104i is connected to a corresponding selection terminal among the six selection terminals 104a to 104f. Thus, at least one of the three antennas 310 to 312 is connected to a corresponding signal path among the six signal paths R11 to R16. In this state, when the selected antenna receives a reception signal, the received reception signal travels through a signal path to which the corresponding antenna is connected among the six signal paths R11 to R16 and is outputted through the signal output terminal 86 to the signal processing circuit.

### (1.3) Structure of High Frequency Module

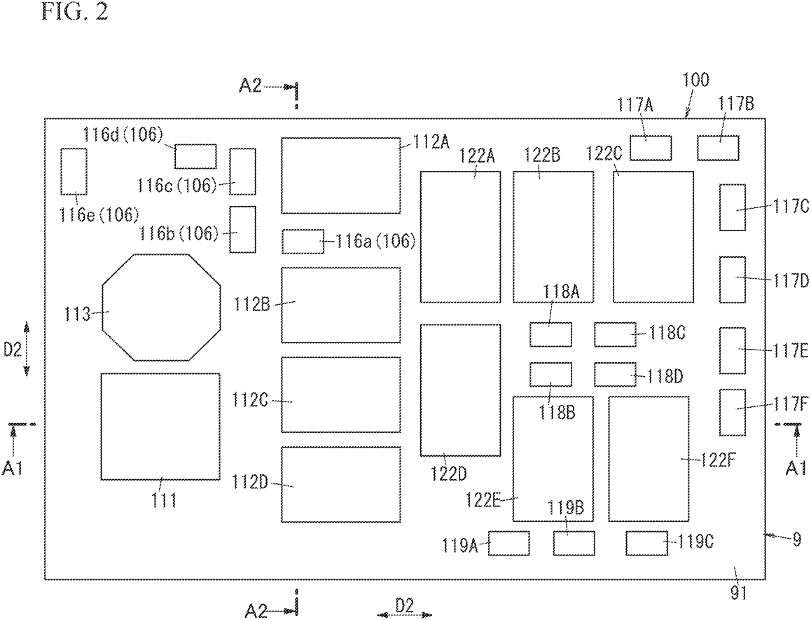

Next, a structure of the high frequency module 100 will be described with reference to FIGS. 2 to 4.

As illustrated in FIGS. 2 to 4, the high frequency module 100 includes the mounting substrate 9, a plurality of circuit components 8, the plurality of external connection terminals 80, resin layers 61 and 62, and the shield layer 5.

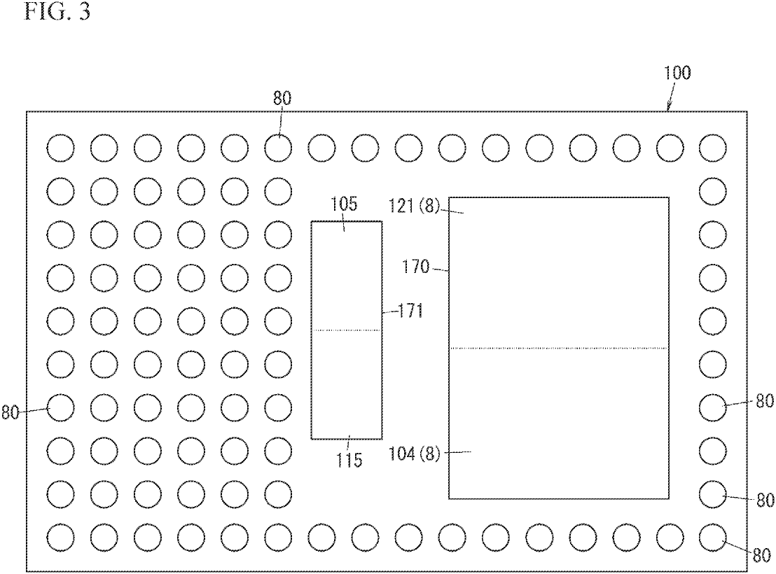

As illustrated in FIG. 4, the mounting substrate 9 includes the first main surface 91 and the second main surface 92 that face each other in a thickness direction D1 of the mounting substrate 9. Each of the first main surface 91 and the second main surface 92 has, for example, a rectangular shape (see FIGS. 2 and 3).

The mounting substrate 9 is, for example, a multilayer substrate including a plurality of dielectric layers and a plurality of conductive layers. The plurality of dielectric layers and the plurality of conductive layers are laminated in the thickness direction D1 of the mounting substrate 9. The plurality of conductive layers include a ground layer. In the high frequency module 100, a plurality of ground terminals 87 and the ground layer are electrically connected with via conductors or the like of the mounting substrate 9 interposed therebetween. Furthermore, although the mounting substrate 9 is, for example, an LTCC (Low Temperature Co-fired Ceramics) substrate, the mounting substrate 9 may be a printed wiring board, an HTCC (High Temperature Co-fired Ceramics) substrate, or a resin multiplayer substrate. Furthermore, the mounting substrate 9 is not limited to an LTCC substrate and may be, for example, a wiring structure.

The first main surface 91 and the second main surface 92 of the mounting substrate 9 are away from each other in the thickness direction D1 of the mounting substrate 9 and intersect with each other in the thickness direction D1 of the mounting substrate 9. The first main surface 91 of the mounting substrate 9 is, for example, orthogonal to the thickness direction D1 of the mounting substrate 9. However, for example, the first main surface 91 may include a side surface or the like of a conductive part as a surface that is not orthogonal to the thickness direction D1. Furthermore, the second main surface 92 of the mounting substrate 9 is, for example, orthogonal to the thickness direction D1 of the mounting substrate 9. However, for example, the second main surface 92 may include a side surface or the like of a conductive part as a surface that is not orthogonal to the thickness direction D1. Furthermore, fine roughness, recesses, or protrusions may be formed in the first main surface 91 and the second main surface 92 of the mounting substrate 9. For example, the mounting substrate 9 has a quadrangular shape when viewed in plan from the thickness direction D1 of the mounting substrate 9. However, the mounting substrate 9 does not necessarily have a quadrangular shape and may have a square shape or shapes other than a square shape (see FIGS. 2 and 3) .

In the description provided below, the thickness direction D1 of the mounting substrate 9 will be described as a first direction D1. Furthermore, a direction orthogonal to the first direction D1 (for example, a direction parallel to one of two pairs of the opposite sides of the first main surface 91 of the mounting substrate 9) will be described as a second direction D2. Furthermore, a direction orthogonal to both the first direction D1 and the second direction D2 (for example, a direction parallel to the other one of the two pairs of the opposite sides of the first main surface 91) will be described as a third direction D3.

The plurality of circuit components 8 are mounted on the first main surface 91 or the second main surface 92 of the mounting substrate 9. The term “mounted” used herein includes a state in which a circuit component 8 is disposed on (mechanically connected to) the first main surface 91 or the second main surface 92 of the mounting substrate 9 and a state in which the circuit component 8 is electrically connected to (an appropriate conductive part of) the mounting substrate 9.

As illustrated in FIG. 2, the plurality of circuit components 8 include the power amplifier 111, the transmission filters 112A to 112D, the reception filters 122A to 122F, the transformer 113, the matching circuit 116, the matching circuits 117A to 117F, the matching circuits 118A to 118D, and the matching circuits 119A to 119C. The above-mentioned circuit components 8 are mounted on the first main surface 91 of the mounting substrate 9. The transformer 113 and the matching circuit 116 configure an output matching circuit 130.

The power amplifier 111 is configured as, for example, an IC chip. The power amplifier 111 includes a substrate having a first main surface and a second main surface that face each other and a circuit part (IC part) including a circuit element mounted on the first main surface side of the substrate. The substrate is, for example, a gallium arsenide substrate. However, the substrate may be a silicon substrate, a silicon germanium substrate, a gallium nitride substrate, or the like. The power amplifier 111 is flip-chip mounted on the first main surface 91 of the mounting substrate 9 in such a manner that the first main surface, out of the first main surface and the second main surface of the substrate, is near the first main surface 91 of the mounting substrate 9 (see FIG. 4). The outer peripheral shape of the power amplifier 111 in a plan view from the first direction D1 of the mounting substrate 9 is, for example, a quadrangular shape (see FIG. 2) .

The transmission filters 112A to 112D and the reception filters 122A to 122F are, for example, acoustic wave filters. In an acoustic wave filter, a plurality of series-arm resonators and a plurality of parallel-arm resonators are acoustic wave resonators. The acoustic wave filters are, for example, SAW (Surface Acoustic Wave) filters using surface acoustic waves. The transmission filters 112A to 112D and the reception filters 122A to 122F are not limited to SAW filters and may be, for example, BAW (Bulk Acoustic Wave) filters. The transmission filters 112A to 112D and the reception filters 122A to 122F may be FBARs (Film Bulk Acoustic Resonators) or the like or may be LC resonant circuits or the like.

The transmission filters 112A to 112D and the reception filters 122A to 122F each include, for example, a substrate having a first main surface and a second main surface that face each other and a circuit part formed on the first main surface side of the substrate (see FIG. 4). The substrate is a piezoelectric substrate. The piezoelectric substrate is, for example, a silicon (Si) substrate. The outer peripheral shape of each of the transmission filters 112A to 112D and the reception filters 122A to 122F in the plan view from the first direction D1 of the mounting substrate 9 is, for example, a quadrangular shape (see FIG. 2). The transmission filters 112A to 112D and the reception filters 122A to 122F are flip-chip mounted on the first main surface 91 of the mounting substrate 9 in such a manner that the first main surface, out of the first main surface and the second main surface of the substrate, is near the mounting substrate 9 (see FIG. 4). Hereinafter, the substrates of the transmission filters 112A to 112D may be described as “substrates 112k”.

The transformer 113 is mounted on the first main surface 91 of the mounting substrate 9. The outer peripheral shape of the transformer 113 in the plan view from the first direction D1 of the mounting substrate 9 is, for example, an octagon shape.

The matching circuit 116, the matching circuits 117A to 117F, the matching circuits 118A to 118D, and the matching circuits 119A to 119C are inductors. The outer peripheral shape of each of the matching circuits 116 to 119C in the plan view from the first direction D1 of the mounting substrate 9 is, for example, a quadrangular shape. The matching circuits 116 to 119C are mounted on the first main surface 91 of the mounting substrate 9.

As illustrated in FIG. 2, the power amplifier 111 and the transformer 113 are disposed along the second direction D2, for example, in a region near one end (left end) in the third direction D3 on the first main surface 91 of the mounting substrate 9. Furthermore, for example, the transmission filters 112A to 112D are disposed along the second direction D2 next to the power amplifier 111 and the transformer 113, on the other end side (right end side) in the third direction D3, on the first main surface 91 of the mounting substrate 9. Furthermore, for example, the reception filters 122A to 122F are disposed horizontally and vertically in a half region near the other end (right end) in the third direction D3 on the first main surface 91 of the mounting substrate 9.

The matching circuit 116 includes at least one (for example, five) inductors 116a to 116e. The plurality of inductors 116a to 116e are, for example, disposed in a region near the transformer 113 and the transmission filters 112A to 112D on the first main surface 91 of the mounting substrate 9. The matching circuits 117A to 117F are, for example, disposed over an area from an edge part on the other end side (right end side) in the third direction D3 to an edge part on one end side (upper end side) in the second direction D2 on the first main surface 91 of the mounting substrate 9. The matching circuits 118A to 118D are, for example, disposed vertically and horizontally in a region surrounded by the reception filters 122A to 122F on the first main surface 91 of the mounting substrate 9. The matching circuits 119A to 119C are, for example, disposed on the other end side (right end side) in the third direction D3 in an edge part on the other end side (lower end side) in the second direction D2 on the first main surface 91 of the mounting substrate 9.

Furthermore, as illustrated in FIG. 3, the plurality of circuit components 8 further include the first switch 104, the second switch 105, the controller 115, and the low noise amplifier 121. These circuit components 8 are mounted on the second main surface 92 of the mounting substrate 9. Furthermore, the plurality of external connection terminals 80 are provided on the second main surface 92 of the mounting substrate 9. In FIG. 3, the second main surface 92 of the mounting substrate 9 in a perspective view from the first main surface 91 side is illustrated.

The first switch 104 and the low noise amplifier 121 are configured to be integrated with each other as an IC chip 170. The IC chip 170 includes a substrate having a first main surface and a second main surface that face each other, and a circuit part (IC part) including a circuit element formed on the first main surface side of the substrate (see FIG. 4). The substrate is, for example, a silicon substrate. The IC chip 170 is flip-chip mounted on the second main surface 92 of the mounting substrate 9 in such a manner that the first main surface, out of the first main surface and the second main surface of the substrate, is near the second main surface 92 of the mounting substrate 9 (see FIG. 4). The outer peripheral shape of the IC chip 170 in the plan view from the first direction D1 of the mounting substrate 9 is, for example, a quadrangular shape (see FIG. 2).

The second switch 150 and the controller 115 are configured to be integrated with each other as an IC chip 171. The IC chip 171 includes a substrate having a first main surface and a second main surface that face each other and a circuit part (IC part) including a circuit element formed on the first main surface side of the substrate. The substrate is, for example, a silicon substrate. The outer peripheral shape of the IC chip 171 in the plan view from the first direction D1 of the mounting substrate 9 is, for example, a quadrangular shape. The IC chip 171 is flip-chip mounted on the second main surface 92 of the mounting substrate 9 in such a manner that the first main surface, out of the first main surface and the second main surface of the substrate, is near the second main surface 92 of the mounting substrate 9.

The plurality of external connection terminals 80 are disposed vertically and horizontally over a region of the second main surface 92 of the mounting substrate 9 in which no circuit component 8 is mounted. Each of the plurality of external connection terminals 80 has, for example, a columnar shape. The plurality of external connection terminals 80 are made of, for example, metal (for example, copper, copper alloy, or the like). The plurality of external connection terminals 80 include the antenna terminals 81 to 83, the signal input terminals 84 and 85, the signal output terminal 86, and the plurality of ground terminals 87. The plurality of ground terminals 87 are electrically connected to the ground layer of the mounting substrate 9. The ground layer is a circuit ground of the high frequency module 100. The plurality of circuit components 8 include a circuit component 8 that is electrically connected to the ground layer.

As illustrated in FIG. 3, the IC chip 171 is disposed at the center in the third direction D3 on the second main surface 92 of the mounting substrate 9. The IC chip 170 is disposed next to the IC chip 170, on the other end side (right side) in the third direction D3, on the second main surface 92 of the mounting substrate 9. The plurality of external connection terminals 80 are disposed vertically and horizontally over a region of the second main surface 92 of the mounting substrate 9 in which neither IC chip 170 nor the IC chip 171 is disposed.

As illustrated in FIG. 4, the resin layer 61 (hereinafter, described as a first resin layer 61) is provided on the first main surface 91 of the mounting substrate 9. The first resin layer 61 covers the plurality of circuit components 8 disposed on the first main surface 91 of the mounting substrate 9. The first resin layer 61 seals the plurality of circuit components 8. More particularly, the first resin layer 61 covers at least part of an outer peripheral surface (in the example of FIG. 4, the whole outer peripheral surface) of a substrate (for example, a substrate 112k) of a specific circuit component 8S (for example, the transmission filters 112A to 112D) among the plurality of circuit components 8. More particularly, at least part of the second main surface of the specific circuit component 8S (that is, a main surface 112a that is far from the mounting substrate 9) (in the example of FIG. 4, the whole second main surface) is not covered by the first resin layer 61, and parts other than the second main surface (the outer peripheral surface and the main surface that is near the mounting substrate 9) are covered by the first resin layer 61. The first resin layer 61 covers the entire circuit components 8 other than the specific circuit component 8S. The first resin layer 61 includes resin. The first resin layer 61 may include filler as well as resin. In FIG. 2, the first resin layer 61 is omitted.

In this embodiment, a main surface 61a of the first resin layer 61 (the main surface that is far from the mounting substrate 9) is a flat surface and is flat relative to the second main surface (that is, the exposed main surface) 112a of the transmission filter 112C. The main surface 61a of the resin layer 61 and the second main surface 112a of the transmission filter 112B are made flat, for example, by being ground together.

The resin layer 62 (hereinafter, may also be referred to as a second resin layer 62) is provided on the second main surface 92 of the mounting substrate 9. The second resin layer 62 covers the plurality of circuit components 8 and the plurality of external connection terminals 80 that are mounted on the second main surface 92 of the mounting substrate 9. The second resin layer 62 seals the plurality of circuit components 8 and the plurality of external connection terminals 80. More particularly, front end surfaces of the plurality of external connection terminals 80 are not covered by the second resin layer 62, and areas other than the front end surfaces are covered by the second resin layer 62. The second resin layer 62 covers the entire circuit components 8. The second resin layer 62 includes resin. The second resin layer 62 may include filler as well as resin. The second resin layer 62 may be made of the same material as that of the first resin layer 61 or may be made of a material different from that of the first resin layer 61. In FIG. 3, the second resin layer 62 is omitted.

The shield layer 5 is made of, for example, metal. The shield layer 5 covers at least part of the first resin layer 61 and a main surface (for example, the main surface 112a) of a specific circuit component 8S (in the example of FIG. 4, the entire part including the corresponding surface and the corresponding main surface). More particularly, the first resin layer 61 covers at least part of a surface of the first resin layer 61 (in the example of FIG. 4, the whole surface) and at least part of a main surface of the specific circuit component 8S (in the example of FIG. 4, the whole main surface). Furthermore, the shield layer 5 covers at least part of an outer peripheral surface 93 of the mounting substrate 9 (in the example of FIG. 4, the whole outer peripheral surface 93) and at least part of an outer peripheral surface 62b of the second resin layer 62 (in the example illustrated in FIG. 4, a part other than a lower edge part of the outer peripheral surface 62b). The shield layer 5 is in contact with the ground layer provided in the mounting substrate 9. Thus, in the high frequency module 100, the potential of the shield layer 5 can be set to be the same as the potential of the ground layer.

### (1.4) Orientations of Inductors in Matching Circuits

The matching circuits 116 to 119C are vertically-wound inductors. A vertically wound inductor represents an inductor whose winding axis (that is, the winding axis of a coil) is orthogonal to the first main surface 91 of the mounting substrate 9.

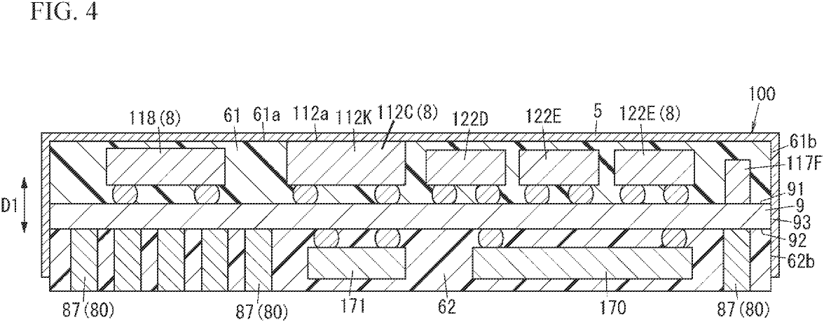

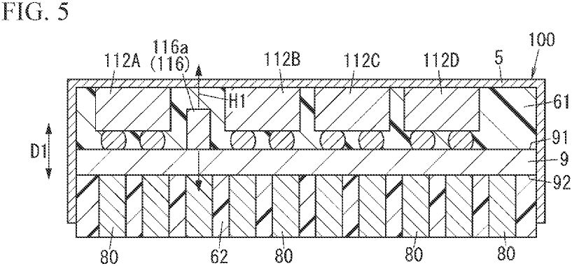

In this embodiment, as illustrated in FIG. 2, the matching circuits 116 to 119C are disposed near the transmission filters 112A to 112C and the reception filters 122A to 122C. In this embodiment, as described above, the transmission filters 112A to 112C and the reception filters 122A to 122C each include an electrically high-resistance silicon substrate. In this embodiment, the matching circuits 116 to 119C are vertically wound inductors. Thus, as illustrated in FIG. 5, a magnetic flux H1 of each of the inductors of the matching circuits 116 to 119C extends in a direction orthogonal to the first main surface 91 of the mounting substrate 9. In FIG. 5, a magnetic flux H1 of the inductor 116a of the matching circuit 116 is illustrated.

Thus, the magnetic fluxes H1 of the matching circuits 116 to 119C are not blocked by the nearby transmission filters 112A to 112D or reception filters 122A to 122F. As a result, the degradation of Q characteristics of the inductors of the matching circuits 116 to 119C can be reduced.

In the case where the matching circuits 116 to 119C are horizontally wound inductors, the winding axis of each of the horizontally wound inductors (that is, the winding axis of a coil) is parallel to the first main surface 91 of the mounting substrate 9. Thus, the magnetic flux of the horizontally wound inductor extends toward both sides of the horizontally wound inductor along the first main surface 91 of the mounting substrate 9. Therefore, in the case where the matching circuits 116 to 119C are disposed next to filters (transmission filters 112A to 112C and reception filters 122A to 122C) each including an electrically high-resistance silicon substrate, the magnetic fluxes of the inductors of the matching circuits 116 to 119C are blocked by the silicon substrates. As a result, Q characteristics of the inductors of the matching circuits 116 to 119C are degraded.

In the case where the matching circuits 116 to 119C are not disposed next to the transmission filters 112A to 112C and the reception filters 122A to 122C, the matching circuits 116 to 119C may be horizontally wound inductors.

### (1.5) Gaps Inside High Frequency Module

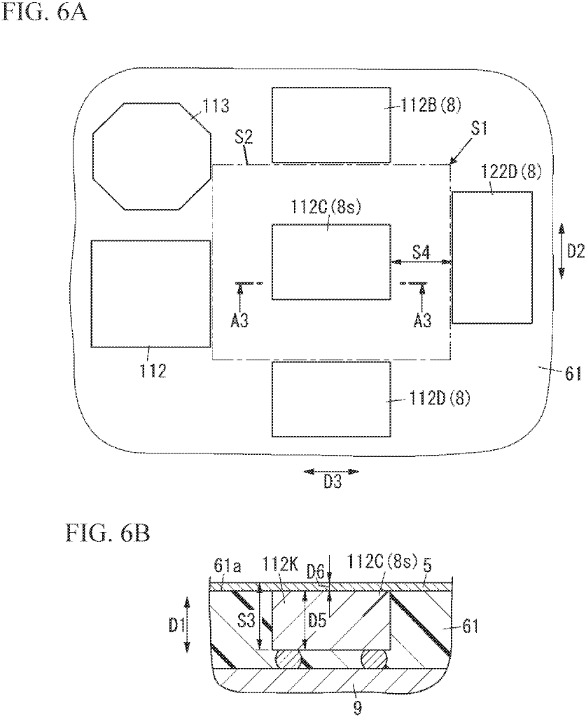

In this embodiment, a gap 180 is arranged within an adjacent region S1 (see FIG. 6A) adjacent to a specific circuit component 8S inside the high frequency module 100 (see FIGS. 7 to 13). A condition “within the adjacent region S1 adjacent to the specific circuit component 8S” is not essential and is not necessarily met.

The above-mentioned “specific circuit component 8S” represents a circuit component 8 that is mounted on the first main surface 91 of the mounting substrate 9, at least part of an outer peripheral surface of the circuit component 8 (in this embodiment, the whole outer peripheral surface) being covered by the resin layer 61, at least part of a main surface that is far from the mounting substrate 9 (in this embodiment, the whole main surface) being covered by (in contact with) the shield layer 5. More particularly, the above-mentioned “specific circuit component 8S” represents a circuit component 8 that is mounted on the first main surface 91 of the mounting substrate 9 and including a substrate (for example, the substrate 112k), at least part of the main surface of the substrate that is far from the mounting substrate 9 (for example, the main surface 112a) (in this example, the whole main surface) being not covered by the resin layer 61, parts other than the main surface being covered by the resin layer 61, at least part of the main surface (in this embodiment, the whole main surface) being covered by (in contact with) the shield layer 5. Specifically, the specific circuit component 8S is, for example, each of the transmission filters 112A to 112D.

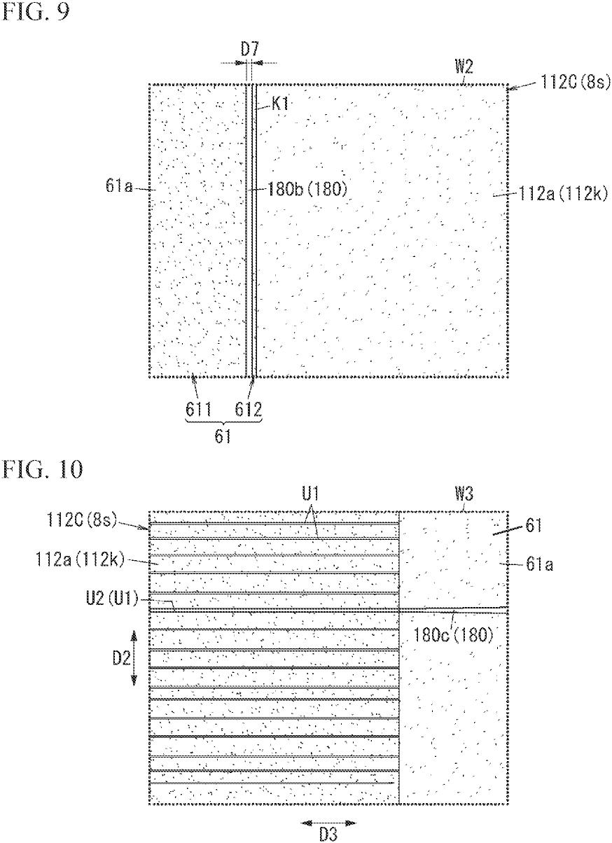

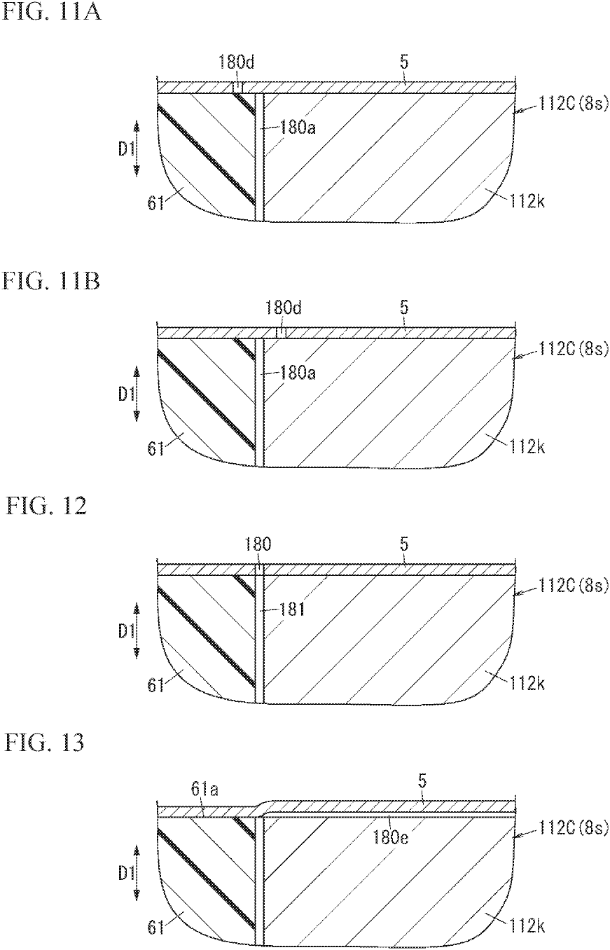

Furthermore, the above-mentioned “inside the high frequency module 100” represents, for example, at least one of a position between the specific circuit component 8S and the resin layer 61 (more particularly, between the substrate of the specific circuit component 8S and the resin layer 61 (see FIG. 8)), a position between the specific circuit component 8S and the shield layer 5 (more particularly, between the substrate of the specific electronic components 8 and the shield layer 5 (see FIG. 13)), a position inside the resin layer 61 (see FIGS. 9 and 10), and a position inside the shield layer 5 (see FIG. 11A).

Furthermore, the above-mentioned “adjacent region S1” represents, when viewed in plan from the first direction D1, a region around the specific circuit component 8S, the region having a boundary S2 for defining inside and outside of the adjacent region S1, no circuit component 8 being disposed between the boundary S2 and the specific circuit component 8S (see FIG. 6A). The “adjacent region S1” includes the resin layer 61 and the shield layer 5 within the boundary S2.

Thus, in the case where the specific circuit component 8S is the transmission filter 112C, as illustrated in FIG. 6A, the boundary S2 of the adjacent region S1 extends up to a side surface 111u of the power amplifier 111 on one side (left side) in the second direction D2 and extends up to a side surface 112u of the reception filter 122D on the other side (right side) in the second direction D2. Furthermore, the boundary S2 of the adjacent region S1 extends up to a side surface 112u of the transmission filter 112C on one side (upper side) in the third direction D3 and extends up to a side surface 112v of the transmission filter 112D on the other side (lower side) in the third direction D3. The side surface 111u is a side surface of the power amplifier 111 that is near the transmission filter 112C. The side surface 122u is a side surface of the reception filter 122D that is near the transmission filter 112C. The side surfaces 112u and 112v are side surfaces of the transmission filters 112B and 112D that are near the transmission filter 112B.

In the case where a distance S4 from the outer peripheral surface of the specific circuit component 8 to the boundary S2 is longer than a thickness D5 of the substrate of the specific circuit component 8S (see FIG. 6B), the distance S4 may be limited to the same size as the thickness D5.

Furthermore, as illustrated in FIG. 6B, the above-mentioned “adjacent region S1” includes a range S3 in the first direction D1. The range S3 includes a range up to the same depth as the thickness D5 of the specific circuit component 8S from the main surface 61a of the resin layer 61. Furthermore, the range S3 also includes the entire range of a thickness D6 of the shield layer 5.

As described above, with the provision of the gap 180 inside the high frequency module 100, the stress generated by the thermal expansion and contraction or the like inside the high frequency module 100 can be reduced. In particular, by arranging the gap 180 only within the range of the adjacent region S1 for the specific circuit component 8S, the influence of the above-mentioned stress on the specific circuit component 8S can be reduced.

Gaps 180 in the positions mentioned above will be described in detail with reference to FIGS. 7 to 13. The transmission filter 112C will be described below as an example of the specific circuit component 8S. Furthermore, the substrate 112k of the transmission filter 112C will be described as a “filter substrate 112k”.

FIG. 7 is a plan view of a certain range including the main surface 112a of the filter substrate 112k and a part near the main surface 112a of the filter substrate 112k when viewed from the first direction D1. The shield layer 5 has a thickness (for example, several tens of microns) that can be seen through. Thus, in FIG. 7, the main surface 112a of the filter substrate 112k and the main surface 61a of the resin layer 61 are illustrated by seeing through the shield layer 5. The main surface 112a of the filter substrate 112k is a main surface of the filter substrate 112k that is far from the mounting substrate 9 and is in contact with the shield layer 5. The main surface 61a of the resin layer 61 is a main surface of the resin layer 61 that is far from the mounting substrate 9 and is in contact with the shield layer 5.

As illustrated in FIG. 7, the resin layer 61 is provided around the filter substrate 112k. In the example of FIG. 7, a gap 180a (180) is arranged in part of the interface between the filter substrate 112k and the resin layer 61. Furthermore, gaps 180b (180) and 180c (180) are also arranged inside the resin layer 61.

### (1.5.1) Details of Range W1 in FIG. 7

FIG. 8 is an enlarged view of a range W1 in FIG. 7. As illustrated in FIG. 8, the gap 180a is arranged between the filter substrate 112k and the resin layer 61. In other words, the gap 180a is arranged, on at least one side (in FIG. 8, one side) among four sides of the main surface 112a of the filter substrate 112k, between the filter substrate 112k and the resin layer 61. The gap 180a may be arranged over the whole one side or may be arranged at part of the one side. Furthermore, the depth (depth in the first direction D1) of the gap 180a may be the same as the thickness of the filter substrate 112k or may be less than the thickness of the filter substrate 112k.

The gap 180a is open at the boundary between the main surface 112a of the filter substrate 112k and the main surface 61a of the resin layer 61. In this embodiment, for example, since the shield layer 5 has a thickness that can be seen through, the gaps 180 can be seen by seeing through the shield layer 5.

As described above, the gap 180a is arranged between the substrate (for example, the filter substrate 112k) of the circuit component 8 and the resin layer 61. Thus, the substrate of the circuit component 8 and the resin layer 61 are capable of absorbing the stress generated by the expansion and contraction caused by temperature changes.

### (1.5.2) Details of Range W2 in FIG. 7

FIG. 9 is an enlarged view of a range W2 in FIG. 7. As illustrated in FIG. 9, the gap 180b is arranged along an interface K1 between the filter substrate 112k and the resin layer 61 with a space D7 interposed between the interface and the gap inside the resin layer 61. The gap 180b is an example of a gap 180 arranged within the adjacent region S1 inside the resin layer 61 that is adjacent to the substrate of the specific circuit component 8S. The gap 180b illustrated in FIG. 9 is an aspect in which the gap 180a illustrated in FIG. 8 is shifted toward the resin layer 61 by the space D7. Part of the resin layer 61 (resin part 612) exists between the gap 180b and the interface K1. That is, the gap 180b at least partially divides the resin layer 61 into a resin part 611 and the resin part 612.

As described above, the gap 180b is arranged along the interface K1 between the substrate (for example, the filter substrate 112k) of the circuit component 8 and the resin layer 61 with the space D7 interposed therebetween inside the resin layer 61. Thus, the resin part 612, which exists between the gap 180b and the interface K1, can absorb bulk waves or the like propagating inside the resin part 611.

### (1.5.3) Details of Range W3 in FIG. 7

FIG. 10 is an enlarged view of a range W3 in FIG. 7. As illustrated in FIG. 10, the main surface 112a of the filter substrate 112k includes a plurality of ground marks U1. The plurality of ground marks U1 are arranged in parallel to one direction (for example, third direction D3). Furthermore, the plurality of ground marks U1 are arranged with spaces interposed therebetween in a direction (second direction D2) that is orthogonal to the one direction. The plurality of ground marks U1 are, for example, formed when the main surface 112a of the filter substrate 11k and the main surface 61a of the resin layer 61 are ground together at the time of manufacturing the high frequency module 100.

As illustrated in FIG. 10, the gap 180c is arranged inside the resin layer 61 and is connected to a ground mark U2, which is one of the plurality of ground marks U1, at an interface K2 between the filter substrate 112k and the resin layer 61. The gap 180c is an example of a gap 180 arranged within the adjacent region S1 inside the resin layer 61 that is adjacent to the substrate of the specific circuit component 8S. The gap 180c illustrated in FIG. 10 is an aspect in which, regarding the gap 180b illustrated in FIG. 8, the gap 180a is displaced so as to be connected to the ground mark U2 at the interface K2. In the example of FIG. 10, the ground mark U2 is the thickest ground mark among the plurality of ground marks U1. However, the ground mark U2 is not necessarily the thickest.

In the example of FIG. 10, the gap 180c extends in parallel to the second direction D2. However, the gap 180c is not necessarily in parallel to the second direction D2. That is, as long as one end portion of the gap 180c is connected to one end portion of the ground mark U2 at the interface K2, the direction in which the gap 180c extends is not particularly limited.

As described above, the gap 180c is arranged inside the resin layer 61 and is connected to the ground mark U2, which is one of the plurality of ground marks U1, at the interface K2 between the substrate (for example, the filter substrate 112k) of the circuit component 8 and the resin layer 61. Thus, for example, by grounding of main surfaces of the substrate of the circuit component 8 and the resin layer 61 (that is, main surfaces that are far from the mounting substrate 9), the gap 180c starting from an end portion of the ground mark U2 of the filter substrate 112k can be formed easily.

### (1.5.4) Details of Cross-section View Taken Along A4-A4 in FIG. 7

FIG. 11A illustrates a cross section taken along A4-A4 in FIG. 7. As illustrated in FIG. 11A, a gap 180d is arranged inside the shield layer 5. The gap 180d is arranged along the thickness direction (first direction D1) of the shield layer 5. The gap 180d extends in a vertical direction on the drawing plane of FIG. 11A (up/down direction on the drawing plane of FIG. 7).

In the example of FIG. 11A, the gap 180d penetrates in the thickness direction of the shield layer 5. However, the gap 180d does not necessarily penetrate in the thickness direction of the shield layer 5. In this case, the gap 180d may be arranged only in a front part of the shield layer 5 in the thickness direction of the shield layer 5 without being arranged in a rear part of the shield layer 5. Alternatively, the gap 180d may be arranged only in a rear part of the shield layer 5 in the thickness direction of the shield layer 5 without being arranged in a front part of the shield layer 5.

Furthermore, in the example of FIG. 11A, the gap 180a is arranged between the filter substrate 112k and the resin layer 61. In this case, the gap 180d inside the shield layer 5 and the gap 180a do not necessarily overlap in the thickness direction of the shield layer 5. In the example of FIG. 11A, the gap 180d is arranged closer to the resin layer 61 than the gap 180a is. However, as illustrated in FIG. 11B, the gap 180d may be arranged closer to the filter substrate 112k than the gap 180a is.

In the examples of FIGS. 11A and 11B, the gap 180a is arranged between the filter substrate 112k and the resin layer 61. However, the gap 180a is not necessarily arranged between the filter substrate 112k and the resin layer 61. In this cases, instead of the gap 180a, an interface is formed between the filter substrate 112k and the resin layer 61. Thus, in this case, the gap 180d is arranged inside the shield layer 5 and does not overlap with the boundary between the filter substrate 112k and the resin layer 61 in the thickness direction of the shield layer 5.

As described above, the gap 180d is arranged along the thickness direction of the shield layer 5. Thus, a situation in which a crack in the shield layer 5 is caused by the stress generated inside the high frequency module 100 can be reduced.

In the example of FIG. 11A, the gap 180d inside the shield layer 5 does not overlap with the gap 180a in the thickness direction of the shield layer 5. However, as illustrated in FIG. 12, the gap 180d and the gap 180a may overlap in the thickness direction of the shield layer 5. In the example of FIG. 12, the gap 180a is arranged between the filter substrate 112k and the resin layer 61. However, the gap 180a is not necessarily arranged between the filter substrate 112k and the resin layer 61. In this case, the gap 180d is arranged inside the shield layer 5 and overlaps with the interface between the filter substrate 112k and the resin layer 61 in the thickness direction of the shield layer 5. In this case, as in the case of FIG. 11A, the stress generated at the shield layer 5 can be absorbed by the gap 180d. As a result, the generation of a crack in the shield layer 5 can be reduced. ]

### (1.5.5) Details of Cross Section Taken Along A5-A5 in FIG. 7

FIG. 13 is a cross-section view taken along A5-A5 in FIG. 7. As illustrated in FIG. 13, a gap 180e is arranged between the filter substrate 112k and the shield layer 5. The gap 180e is partially arranged at the main surface 112a of the filter substrate 112k. That is, the main surface 112a of the filter substrate 112k and the shield layer 5 are isolated from each other in a part where the gap 180e is arranged but are in contact with each other in a part where the gap 180e is not arranged.

As described above, the gap 180e is arranged between the substrate (for example, the filter substrate 112k) of the circuit component 8 and the shield layer 5. Thus, the stress generated at the substrate of the circuit component 8 can be absorbed. As a result, the generation of cracks in the shield layer 5 and the substrate of the circuit component 8 can be reduced.

The gap 180e is partially arranged at a main surface of the substrate of the circuit component 8. That is, the substrate of the circuit component 8 and the shield layer 5 are in contact with each other in the part where the gap 180e is not arranged. Thus, the generation of cracks in the shield layer 5 and the substrate of the circuit component 8 can be reduced without impeding the heat dissipation function for causing the heat generated at the circuit component 8 to be dissipated from the shield layer 5.

Positions of the ranges W1 to W3, the cross section taken along A4-A4, and the cross section taken along A5-A5 illustrated in FIG. 7 are examples and may be different from the positions illustrate in FIG. 7. Furthermore, in FIG. 7, the gaps 180 are arranged at all the five positions (FIGS. 8 to 11A and FIG. 13). However, the gap 180 may be arranged at at least one of the five positions.

### (1.5.6) Ground Mark on Main Surface of Specific Circuit Component

In this embodiment, as illustrated in FIG. 10, the plurality of ground marks U1 are arranged at a main surface of the substrate of the specific circuit component 8S (the main surface that is far from the mounting substrate 9). As described above, the plurality of ground marks U1 are, for example, formed when the main surface (for example, the main surface 112a) of the substrate of the specific circuit component 8S that is far from the mounting substrate 9 and the main surface 61a of the resin layer 61 that is far from the mounting substrate 9 are ground together at the time of manufacturing the high frequency module 100.

As described above, the plurality of ground marks U1 are arranged at the main surface of the substrate of the specific circuit component 8S. Thus, the reflectivity of the main surface of the substrate of the specific circuit component 8S is different from the reflectivity of the main surface 61a of the resin layer 61, and the arrangement of the specific circuit component 8S on the main surface 61a of the resin layer 61 can be easily viewed from the outside. Accordingly, based on the arrangement of the specific circuit component 8S at the mounting substrate 9, the orientation of the high frequency module 100 can be visually confirmed. Furthermore, the surface area of the substrate of the specific circuit component 8S can be increased by the ground marks U1, and the heat dissipation characteristics of the specific circuit component 8S can be improved.

### (1.6) Method for Manufacturing High Frequency Module

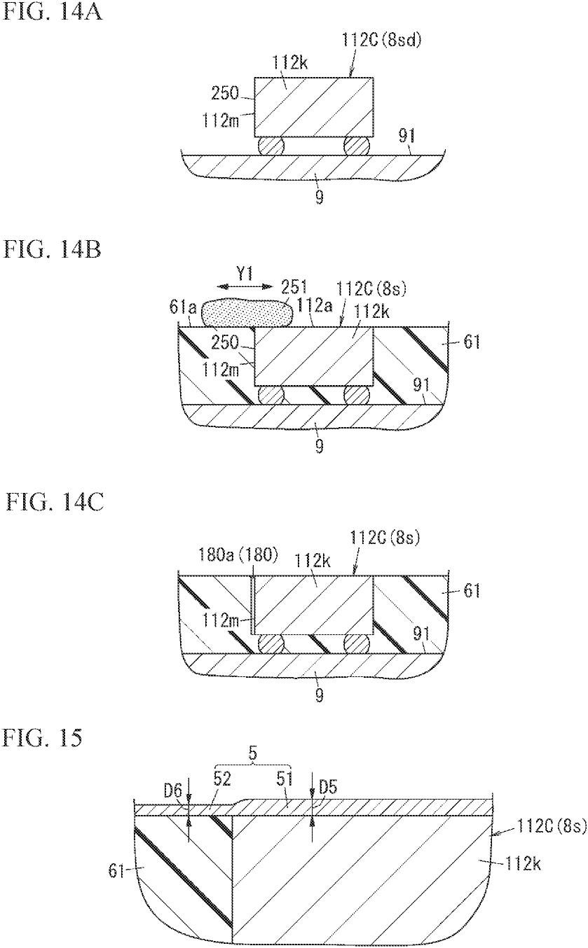

Next, a method for manufacturing the high frequency module 100 (more particularly, a method for forming the gaps 180) will be described with reference to FIGS. 14A to 14C. A method for forming the gap 180a between the substrate of the circuit component 8 and the resin layer 61 will be described below. Furthermore, the transmission filter 112C is illustrated as an example of the circuit component 8.

The transmission filter 112C is mounted on the first main surface 91 of the mounting substrate 9 (see FIG. 14A). Then, a release agent 250 is applied to a region 112m (in FIG. 14A, a left-side surface of the filter substrate 112k) in which the gap 180a is to be formed on an outer peripheral surface of the substrate (filter substrate) 112k of the transmission filter 112C (see FIG. 14A).

Then, the resin layer 61 is formed on the first main surface 91 of the mounting substrate 9 in such a manner that the main surface (the main surface that is far from the mounting substrate 9) 112a of the substrate 112k of the transmission filter 112C is not covered by the resin layer 61 and parts of the transmission filter 112C other than the main surface 112a are covered by the resin layer 61 (see FIG. 14B). At this time, in the case where other circuit components 8 are mounted on the first main surface 91, the resin layer 61 is formed to cover the other circuit components 8. Then, the main surface 112a of the transmission filter 112C and the main surface (the main surface that is far from the mounting substrate 9) 61a of the resin layer 61 are ground together by a grinding tool 251 (see FIG. 14B). At this time, the grinding tool 251 is moved to reciprocate across the region 112m as indicated by an arrow Y1 on the main surface 112a of the transmission filter 112C and the main surface 61a of the resin layer 61.

At the time of grinding using the grinding tool 251, the frictional force from the grinding tool 251 on the main surfaces 112a and 61a operates in a direction for causing the substrate 112k and the resin layer 61 to be separated from each other in the region 112m. Furthermore, since the release agent 250 is applied to the region 112m of the filter substrate 112k, due to the above-mentioned frictional force on the filter substrate 112k and the resin layer 61, the filter substrate 112k and the resin layer 61 are separated from each other in the region 112m (see FIG. 14C). The separated part serves as the gap 180a. Thus, the gap 180a is formed.

### (1.7) Major Effects

As described above, the high frequency module 100 according to an embodiment includes the mounting substrate 9, the circuit component 8S, the resin layer 61, and the shield layer 5. The mounting substrate 9 has the first main surface 91 and the second main surface 92 that face each other. The circuit component 8S is mounted on the first main surface 91 of the mounting substrate 9. The resin layer 61 is disposed on the first main surface 91 of the mounting substrate 9 and covers at least part of an outer peripheral surface of the circuit component 8S. The shield layer 5 covers at least part of the resin layer 61 and a main surface (for example, the main surface 112a) of the circuit component 8S that is far from the mounting substrate 9. The high frequency module 100 has a gap 180 at at least one of a position between the circuit component 8S and the resin layer 61, a position between the circuit component 8S and the shield layer 5, a position inside the resin layer 61, and a position inside the shield layer 5. With this arrangement, the stress generated by the thermal expansion and contraction inside the high frequency module 100 can be reduced by the gap 180.

### (1.8) Modifications

Next, modifications of an embodiment will be described.

### First Modification

As illustrated in FIG. 15, in the embodiment described above, the shield layer 5 includes a first part 51 and a second part 52, and the thickness of the shield layer 5 may be different between the first part 51 and the second part 52. The first part 51 is a part provided on a main surface of the substrate of the specific circuit component 8S that is far from the mounting substrate 9 (for example, the main surface 112a of the filter substrate 112k of the transmission filter 112C). The second part 52 is a part provided on the main surface 61a of the resin layer 61 that is far from the mounting substrate 9.

More particularly, the first thickness D5 is more than the second thickness D6, where the thickness of the first part 51 is represented by the first thickness D5 and the thickness of the second part 52 is represented by the second thickness D6. Thus, only the thickness of the part of the shield layer 5 that is provided on the specific circuit component 8S can be increased. As a result, the heat dissipation characteristics of the specific circuit component 8S on the shield layer 5 can be improved.

### Second Modification

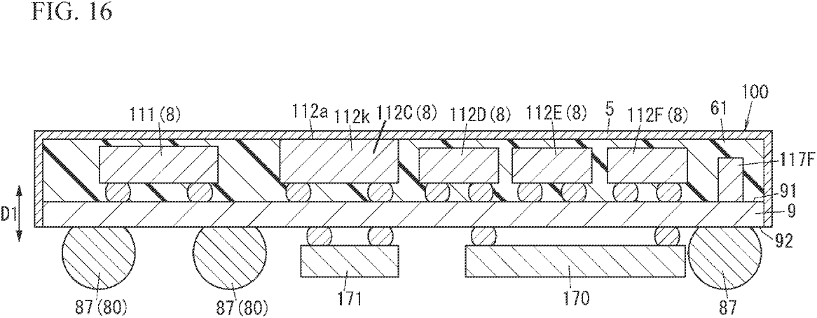

In the embodiment described above, the external connection terminals 80 each have a columnar shape. However, as illustrated in FIG. 16, each of the external connection terminals 80 may have a spherical shape (ball bump) .

### Aspects

Aspects described below are disclosed herein.

According to a first aspect, a high frequency module (100) includes a mounting substrate (9), a circuit component (8S), a resin layer (61), and a shield layer (5). The mounting substrate (9) has a first main surface (91) and a second main surface (92) that face each other. The circuit component (8S) is mounted on the first main surface (91) of the mounting substrate (9). The resin layer (61) is disposed on the first main surface (91) of the mounting substrate (9) and covers at least part of an outer peripheral surface of the circuit component (8S). The shield layer (5) covers at least part of the resin layer (61) and a main surface (112a) of the circuit component (8S) that is far from the mounting substrate (9). The high frequency module (1) has a gap (180) at at least one of a position between the circuit component (8S) and the resin layer (61), a position between the circuit component (8S) and the shield layer (5), a position inside the resin layer (61), and a position inside the shield layer (5).

With this arrangement, the stress generated by the thermal expansion and contraction or the like inside the high frequency module (100) can be reduced by the gap (180).

According to a second aspect, in the high frequency module (100) according to the first aspect, the circuit component (8S) includes a substrate (112k). The gap (180) is arranged at at least one of a position between the substrate (112k) of the circuit component (8S) and the resin layer (61) and a position between the substrate (112k) of the circuit component (8S) and the shield layer (5).

With this arrangement, by limiting the circuit component (8S) to a circuit component that includes the substrate (112k), a situation in which the substrate (112k) of the circuit component (8S) is affected by the above-mentioned stress can be reduced.

According to a third aspect, in the high frequency module (100) according to the first or second aspect, the gap (180b, 180c) is arranged within an adjacent region (S1) inside the resin layer (61) that is adjacent to the circuit component (8S).

With this arrangement, the gap (180b, 180c) can be arranged within the adjacent region (S1) of the resin layer (61) that is adjacent to the circuit component (8S).

According to a fourth aspect, in the high frequency module (100) according to any one of the first to third aspects, the gap (180b) is arranged along an interface (K1) between the circuit component (8S) and the resin layer (61) with a space interposed between the interface (K1) and the gap (180b) inside the resin layer (61).

With this arrangement, bulk waves can be absorbed by a resin part (612) that exists between the circuit component (8S) and the gap (180b).

According to a fifth aspect, in the high frequency module (100) according to any one of the first to fourth aspects, the main surface (112a) of the circuit component (8S) includes a plurality of ground marks (U1).

With this arrangement, due to the plurality of ground marks (U1), the reflectivity of the main surface (112a) of the circuit component (8S) and the reflectivity of the main surface (61a) of the resin layer (61) are different. Thus, arrangement of the specific circuit component (8S) on the main surface (61a) of the resin layer (61) can be easily viewed from the outside. Furthermore, the surface area of the circuit component (8S) is increased by the plurality of ground marks (U1), and the heat dissipation characteristics of the circuit component (8S) can be improved.

According to a sixth aspect, in the high frequency module (100) according to the fifth aspect, the gap (180) is arranged inside the resin layer (61) and is connected to a ground mark (U2) that is one of the plurality of ground marks (U1) at the interface between the circuit component (8S) and the resin layer (61).

With this arrangement, the stress generated by the thermal expansion and contraction or the like inside the resin layer (61) can be reduced by the gap (180).

According to a seventh aspect, in the high frequency module (100) according to any one of the first to sixth aspects, the gap (180d) is arranged along a thickness direction (D1) of the shield layer (5) inside the shield layer (5) and does not overlap with an interface between the circuit component (8S) and the resin layer (61) in the thickness direction (D1) of the shield layer (5).

With this arrangement, the stress generated at the shield layer (5) can be absorbed by the gap (180d). As a result, the generation of a crack in the shield layer (5) can be reduced.

According to an eighth aspect, in the high frequency module (100) according to any one of the first to sixth aspects, the gap (180) is arranged along a thickness direction (D) of the shield layer (5) inside the shield layer (5) and overlaps with an interface between the circuit component (8S) and the resin layer (61) in the thickness direction (D1) of the shield layer (5).

With this arrangement, the stress generated at the shield layer (5) can be absorbed by the gap (180). As a result, the generation of a crack in the shield layer (5) can be reduced.

According to a ninth aspect, in the high frequency module (100) according to any one of the first to eighth aspects, a thickness of a part of the shield layer (5) that is provided on the main surface (112a) of the circuit component (8S) is set to a first thickness (D5), and a thickness of a part of the shield layer (5) that is provided on a main surface of the resin layer (61) that is far from the mounting substrate (9) is set to a second thickness (D6). The first thickness (D5) is more than the second thickness (D6).

With this arrangement, the heat dissipation characteristics of the circuit component (8S) at the shield layer (5) can be improved.

According to a tenth aspect, a communication apparatus (300) includes the high frequency module (100) according to any one of the first to ninth aspects and a signal processing circuit (301). The signal processing circuit (301) is connected to the high frequency module (100) and performs signal processing on a high frequency signal.

With this arrangement, the communication apparatus (300) that achieves the above-mentioned effects of the high frequency module (100) can be provided.

| | |
|---|---|
| 5 | shield layer |
| 8 | circuit component |
| 8S | specific circuit component (circuit component) |
| 9 | mounting substrate |
| 11C | transmission filter |
| 11k | filter substrate |
| 51 | first part |
| 52 | second part |
| 61 | first resin layer (resin layer) |
| 61a | main surface |
| 61b | outer peripheral surface |
| 62 | second resin layer |
| 62b | outer peripheral surface |
| 80 | external connection terminal |
| 81 to 83 | antenna terminal |
| 84, 85 | signal input terminal |
| 86 | signal output terminal |
| 87 | ground terminal |
| 91 | first main surface |
| 92 | second main surface |
| 93 | outer peripheral surface |
| 100 | high frequency module |
| 104 | first switch |
| 104a to 104f | selection terminal |
| 104g to 104i | common terminal |
| 105 | second switch |
| 105a to 105d | selection terminal |
| 105 e | common terminal |
| 111 | power amplifier |
| 111u | side surface |
| 112 a | main surface |
| 112A to 112D | transmission filter |
| 112 k | filter substrate (substrate) |
| 112m | region |
| 112u, 112v | side surface |
| 113 | transformer |
| 115 | controller |
| 116 | matching circuit |
| 116a to 116e | inductor |
| 117A to 117F | matching circuit |
| 118A to 118D | matching circuit |
| 119A to 119C | matching circuit |
| 121 low noise | amplifier |
| 122A to 122F | reception filter |
| 122 u | side surface |
| 123A to 123D | connection point |
| 130 | output matching circuit |
| 150 | second switch |
| 170, 171 | IC chip |
| 180, 180a to 180e | gap |
| 250 | release agent |
| 251 | grinding tool |
| 300 | communication apparatus |
| 301 | signal processing circuit |
| 302 | RF signal processing circuit |
| 303 | baseband signal processing circuit |
| 310 to 312 | antenna |
| 611, 612 | resin part |
| D1 | first direction |
| D2 | second direction |
| D3 | third direction |
| D5 | first thickness |
| D6 | second thickness |
| D7 | space |
| H1 | magnetic flux |
| K1, K2 | interface |
| R1, R11 to R16, T1, T11 to T14 | signal path |
| S1 | adjacent region |
| S2 | boundary |
| S3 | range |
| S4 | distance |
| U1, U2 | ground mark |
| W1 to W3 | range |
| Y1 | arrow |

1. A high frequency module comprising:
a mounting substrate having a first main surface and a second main surface, the first main surface and the second main surface facing each other;
a circuit component mounted on the first main surface of the mounting substrate;
a resin layer disposed on the first main surface of the mounting substrate and covering at least a part of an outer peripheral surface of the circuit component; and
a shield layer covering at least a part of the resin layer and a main surface of the circuit component farther from the mounting substrate,
wherein a gap is arranged at at least one of a position between the circuit component and the resin layer, a position between the circuit component and the shield layer, a position inside the resin layer, and a position inside the shield layer.

2. The high frequency module according to claim 1,
wherein the circuit component includes a substrate, and
wherein the gap is arranged at at least one of a position between the substrate of the circuit component and the resin layer and a position between the substrate of the circuit component and the shield layer.

3. The high frequency module according to claim 1, wherein the gap is arranged within an adjacent region inside the resin layer adjacent to the circuit component.

4. The high frequency module according to claim 1, wherein the gap is arranged along an interface between the circuit component and the resin layer with a space interposed between the interface and the gap inside the resin layer.

5. The high frequency module according to claim 1, wherein the main surface of the circuit component includes a plurality of ground marks.

6. The high frequency module according to claim 5, wherein the gap is arranged inside the resin layer and is connected to one of the plurality of ground marks at the interface between the circuit component and the resin layer.

7. The high frequency module according to claim 1, wherein the gap
is arranged along a thickness direction of the shield layer inside the shield layer, and
does not overlap with an interface between the circuit component and the resin layer in the thickness direction of the shield layer.

8. The high frequency module according to claim 1, wherein the gap
is arranged along a thickness direction of the shield layer inside the shield layer, and
overlaps with an interface between the circuit component and the resin layer in the thickness direction of the shield layer.

9. The high frequency module according to claim 1,
wherein a thickness of a part of the shield layer provided on the main surface of the circuit component is set to a first thickness,
wherein a thickness of a part of the shield layer provided on a main surface of the resin layer farther from the mounting substrate is set to a second thickness, and
wherein the first thickness is more than the second thickness.

10. A communication apparatus comprising:
the high frequency module according to claim 1; and
a signal processing circuit connected to the high frequency module and performs signal processing on a high frequency signal.

11. The high frequency module according to claim 2, wherein the gap is arranged within an adjacent region inside the resin layer adjacent to the circuit component.

12. The high frequency module according to claim 2, wherein the gap is arranged along an interface between the circuit component and the resin layer with a space interposed between the interface and the gap inside the resin layer.

13. The high frequency module according to claim 3, wherein the gap is arranged along an interface between the circuit component and the resin layer with a space interposed between the interface and the gap inside the resin layer.

14. The high frequency module according to claim 2, wherein the main surface of the circuit component includes a plurality of ground marks.

15. The high frequency module according to claim 3, wherein the main surface of the circuit component includes a plurality of ground marks.

16. The high frequency module according to claim 4, wherein the main surface of the circuit component includes a plurality of ground marks.

17. The high frequency module according to claim 2, wherein the gap
is arranged along a thickness direction of the shield layer inside the shield layer, and
does not overlap with an interface between the circuit component and the resin layer in the thickness direction of the shield layer.

18. The high frequency module according to claim 3, wherein the gap
is arranged along a thickness direction of the shield layer inside the shield layer, and
does not overlap with an interface between the circuit component and the resin layer in the thickness direction of the shield layer.

19. The high frequency module according to claim 4, wherein the gap
is arranged along a thickness direction of the shield layer inside the shield layer, and
does not overlap with the interface between the circuit component and the resin layer in the thickness direction of the shield layer.

20. The high frequency module according to claim 5, wherein the gap
is arranged along a thickness direction of the shield layer inside the shield layer, and
does not overlap with an interface between the circuit component and the resin layer in the thickness direction of the shield layer.
